(19) United States
(12) Patent Application Publication
(10) Pub. No.: US 2023/0292404 A1
(43) Pub. Date: Sep. 14, 2023

(54) HEATER AND METHOD OF MANUFACTURING THE SAME, AND AN APPARATUS FOR TREATING SUBSTRATE

(71) Applicant: SEMES CO., LTD., Cheonan-si (KR)

(72) Inventor: Jong Seok SEO, Cheonan-si (KR)

(73) Assignee: SEMES CO., LTD., Cheonan-si (KR)

(21) Appl. No.: 18/162,229

(22) Filed: Jan. 31, 2023

(30) Foreign Application Priority Data
Mar. 8, 2022 (KR) 10-2022-0029530

(51) Int. Cl. H05B 3/00; H01L 21/67; B23K 26/351; H01C 17/22; H01C 17/06; C25D 7/00

(52) U.S. Cl. CPC H05B 3/0014; H01L 21/67103; B23K 26/351; H01C 17/22; H01C 17/06; C25D 7/00; H05B 2203/017

(57) ABSTRACT

An apparatus for treating a substrate is provided. The apparatus includes: a support member provided in a process chamber and configured to support the substrate; and a heater heating element provided in the support member and configured to heat the substrate, wherein at least a part of the heater heating element comprises a first region to which a laser trimming process is applied, at least another part of the heater heating element comprises a second region on which a resistance adjusting material layer is implemented by an electrolytic plating process, and the amount of heat generated in the first region that is at least a part of the heater heating element is increased by performing the laser trimming process and the amount of heat generated in the second region that is at least another part of the heater heating element is decreased by forming the resistance adjusting material layer.

### CROSS-REFERENCE TO RELATED APPLICATION(S)

This application claims the benefit under 35 USC § 119(a) of Korean Patent Application No. 10-2022-0029530, filed on Mar. 8, 2022, in the Korean Intellectual Property Office, the entire disclosure of which is incorporated herein by reference for all purposes.

### BACKGROUND

### 1. Field

The following description relates to a heater for heating a substrate, a method of manufacturing the heater, and an apparatus for treating a substrate.

### 2. Description of Related Art

To fabricate a semiconductor device, various processes, such as photolithography, etching, deposition, ion-implantation, and cleaning processes, are performed and in some cases, these processes may be performed while the substrate is heated. For example, a photolithography process is a process to form a pattern and plays an important role in achieving high integration of semiconductor devices. The photolithography process mainly includes a coating process, an exposing process, and a developing process. A bake process is performed before the exposure process is performed after the developing process, and after the exposure process is performed. The bake process is a process of heat-treating a substrate, in which the substrate placed on a heating plate is heat-treated with heat provided from a heater. In addition, in order to realize a predetermined deposition temperature during a deposition process, a heating member may be provided to a support unit on which the substrate is seated. Acquisition of temperature uniformity is an important factor in the process of heating a substrate.

Korean Patent Publication No. 20190014254A discloses a related art.

### SUMMARY

This summary is provided to introduce a selection of concepts in a simplified form that are further described below in the Detailed Description. This summary is not intended to identify key features or essential features of the claimed subject matter, nor is it intended to be used as an aid in determining the scope of the claimed subject matter.

The present disclosure is to solve various problems including the problem described above and aims to provide a heater capable of attaining temperature uniformity, a method of manufacturing the heater, and an apparatus for treating a substrate. However, these solutions are for illustrative purpose only, and the scope of the present invention is not limited thereto.

In one general aspect, there is provided a method of manufacturing a heater including: performing a trimming process on at least a part of a heater heating element for heating a substrate; and forming a resistance adjusting material layer on at least another part of the heater heating element.

In the method of manufacturing a heater, the trimming process may include a laser trimming process.

In the method of manufacturing a heater, the forming of the resistance adjusting material layer may include performing a plating process on at least another part of the heater heating element. The plating process may include an electrolytic plating process.

In the method of manufacturing a heater, the forming of the resistance adjusting material layer may include performing a deposition process on at least another part of the heater heating element.

In the method of manufacturing a heater, the forming of the resistance adjusting material layer may include performing a printing process on at least another part of the heater heating element.

In the method of manufacturing a heater, the resistance adjusting material layer may be made of the same material as a material constituting the heater heating element.

In the method of manufacturing a heater, the resistance adjusting material layer may be a material layer including at least some elements of a compound constituting the heater heating element.

In the method for manufacturing the heater, before performing the trimming process and forming the resistance adjusting material layer, measuring an amount of heat generated by the heater heating element and then performing the trimming process and forming the resistance is adjusting material layer may be performed on the basis of the measured amount of heat.

In the method of manufacturing a heater, the amount of heat generated in a first region that is at least a part of the heater heating element to which the laser trimming process is to be applied may be relatively lower than the amount of heat generated in a second region that is at least another part of the heater heating element on which the resistance adjusting material layer is to be formed.

In the method of manufacturing a heater, the amount of heat generated in the first region that is at least a part of the heater heating element may be increased by performing the trimming process, and the amount of heat generated in the second region that is at least another part of the heater heating element may be decreased by forming the resistance adjusting material layer.

In the method of manufacturing a heater, the amount of heat generated by the heater heating element may be measured using a thermal imaging camera.

In the method of manufacturing a heater, before performing the laser trimming process and forming the resistance adjusting material layer, measuring an electrical resistance value of the heater heating element may be performed, and then performing the laser trimming process and forming the resistance adjusting material layer may be performed on the basis of the electrical resistance value.

In the method of manufacturing a heater, an electrical resistance value of a first region that is at least a part of the heater heating element to which the trimming process is to be applied may be relatively lower than an electrical resistance value of a second region that is at least another part of the heater heating element on which the resistance adjusting material layer is to be formed.

In the method of manufacturing a heater, the electrical resistance value of the first region that is at least a part of the heater heating element may be increased by performing the laser trimming process, and the electrical resistance value of the second region that is at least another part of the heater heating element may be decreased by forming the resistance adjusting material layer.

In the method of manufacturing a heater, the heater heating element before performing the trimming process and forming the resistance adjusting material layer may be implemented by a printed circuit sintering process.

In another general aspect, there is provided a heater including a heater heating element configured to heat a substrate, wherein at least a part of the heater heating element includes a first region to which a trimming process is applied and at least another part of the heater heating element includes a second region on which a resistance adjusting material layer is formed.

In the heater, the resistance adjusting material layer may be a plating layer implemented by a plating process on at least another part of the heater heating element.

In the heater, the resistance adjusting material layer may be a deposition layer implemented by a deposition process on at least another part of the heater heating element.

In the heater, the resistance adjusting material layer may be a material layer implemented by a printing process on at least another part of the heater heating element.

In still another general aspect, there is provided an apparatus for treating a substrate including: a process chamber capable of accommodating a substrate; a support member provided in the process chamber and configured to support the substrate; a heater heating element provided in the support member and configured to heat the substrate; and a voltage source configured to apply an electric current to the heater heating element, wherein at least a part of the heater heating element includes a first region to which a laser trimming process is applied, at least another part of the heater heating element include a second region on which a resistance adjusting material layer is implemented by an electrolytic plating process, and the amount of heat generated in the first region that is at least a part of the heater heating element is increased by performing the laser trimming process and the amount of heat generated in the second region that is at least another part of the heater heating element is decreased by forming the resistance adjusting material layer, so that a temperature distribution of the heater heating element is uniform.

Other features and aspects will be apparent from the following detailed description, the drawings, and the claims.

### BRIEF DESCRIPTION OF THE DRAWINGS

FIG. 1 is a plan view illustrating a facility for treating a substrate according to an embodiment of the present disclosure.

FIG. 2 is a sectional view of the facility of FIG. 1, taken along line A-A of FIG. 1.

FIG. 3 is a sectional view of the facility of FIG. 1, taken along line B-B of FIG. 1.

FIG. 4 is a sectional view of the facility of FIG. 1, taken along line C-C of FIG. 1.

FIG. 5 is a cross-sectional view of an apparatus for treating a substrate that constitutes the facility of FIG. 1.

FIG. 6 is a plan view of a support member and a heater heating element of FIG. 5.

FIG. 7 is a graph comparing heating wire sintering resistance values and resistance values adjusted by laser trimming.

FIG. 8 is a graph comparing heating wire sintering resistance values and resistance values adjusted by electroplating and laser trimming.

FIGS. 9 and 10 are flowcharts illustrating a method of manufacturing a heater according to various embodiments of the present disclosure.

FIG. 11 is a cross-sectional view of a facility of treating a substrate according to another embodiment of the present disclosure.

FIG. 12 is a plan view of a support member and a heat heating member of FIG. 11.

Throughout the drawings and the detailed description, unless otherwise described, the same drawing reference numerals will be understood to refer to the same elements, features, and structures. The relative size and depiction of these elements may be exaggerated for clarity, illustration, and convenience.

### DETAILED DESCRIPTION

Hereinafter, various embodiments of the present disclosure will be described in detail with reference to the accompanying drawings.

The present disclosure may be embodied in many different forms and should not be construed as being limited to the embodiments set forth herein. Rather, these embodiments are provided so that this disclosure will be thorough and complete, and will fully convey the concept of the invention to one of ordinary skill in the art. Also, thickness or sizes of layers in the drawings are exaggerated for convenience of explanation and clarity.

Hereinafter, the present disclosure will be described more fully with reference to the accompanying drawings, in which exemplary embodiments of the present disclosure are shown. In the drawings, for example, according to the manufacturing techniques and/or tolerances, shapes of the illustrated elements may be modified. Thus, the present disclosure should not be construed as being limited to the embodiments set forth herein, and should include, for example, variations in the shapes caused during manufacturing.

An apparatus for treating a substrate that includes a heater capable of attaining temperature uniformity according to the present embodiment may be used to perform a photolithography process on a substrate, such as a semiconductor wafer or a flat panel display panel. In particular, is the apparatus for treating a substrate according to the present embodiment may be connected to an exposing apparatus and used to perform a coating processing and a developing process on a substrate. Hereinafter, a circular wafer will be described as an example of a substrate.

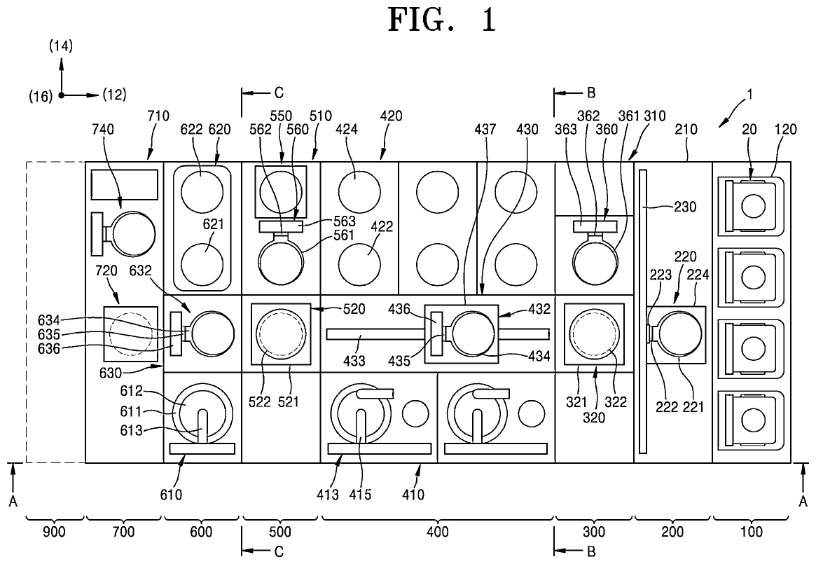

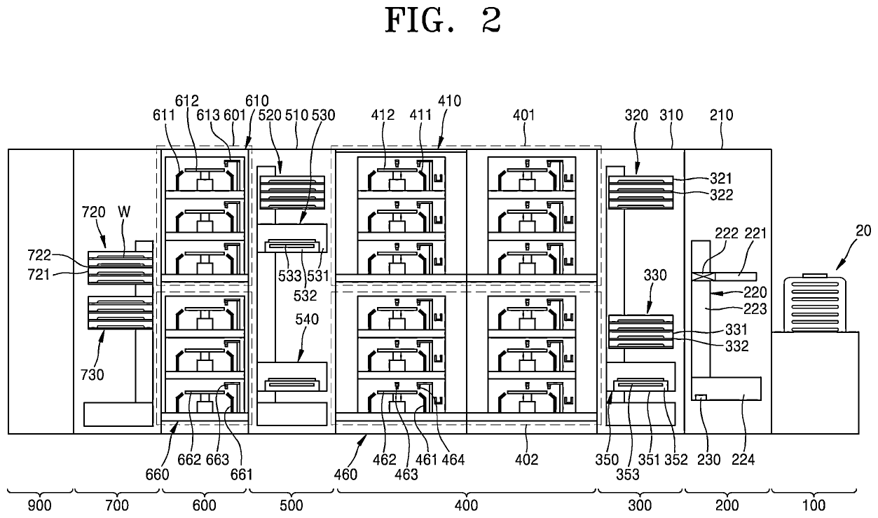

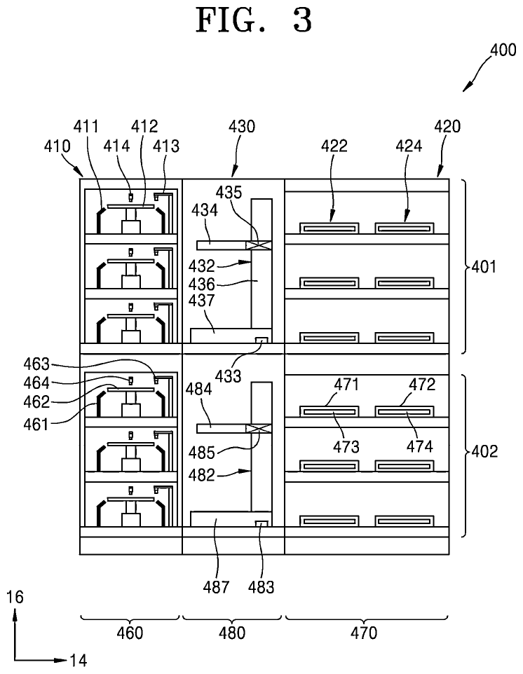

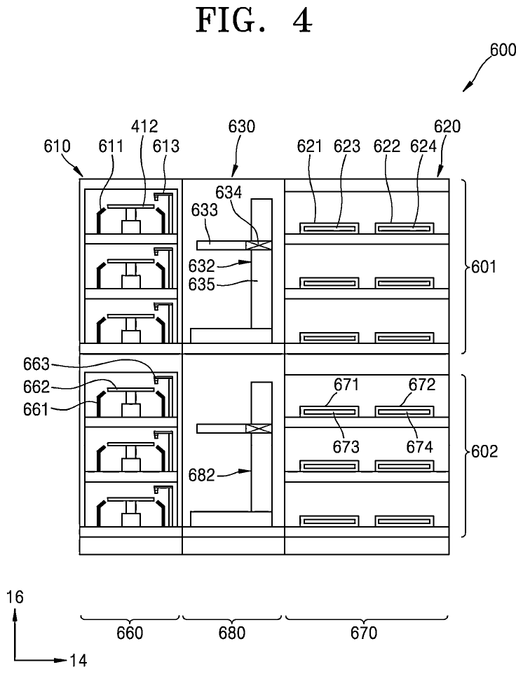

Referring to FIGS. 1 to 4, a substrate treatment facility 1 includes a load port 100, an index module 200, a first buffer module 300, a coating and developing module 400, a second buffer module 500, a pre/post-exposure treatment module 600, and an interface module 700. The load port 100, the index module 200, the first buffer module 300, the coating and developing module 400, the second buffer module 500, the pre/post-exposure treatment module 600, and the interface module 700 are sequentially disposed in a row in one direction.

Hereinafter, a direction in which the load port 100, the index module 200, the first buffer module 300, the coating and developing module 400, the second buffer module 500, the pre/post-exposure treatment module 600, and the interface module 700 are disposed will be referred to as a first direction 12, a direction that is perpendicular to the first direction 12 when viewed from the top will be referred to as a second direction 14, and a direction that is perpendicular to the first direction 12 and the second direction 14 will be referred to as a third direction 16.

A substrate W is moved while being received in a cassette 20. Here, the cassette 20 has a structure that is sealed from the outside. For example, a front open unified pod (FOUP) that has a door on the front side may be used as the cassette 20.

Hereinafter, the load port 100, the index module 200, the first buffer module 300, the coating and developing module 400, the second buffer module 500, the pre/post-exposure treatment module 600, and the interface module 700 will be described in detail.

The load port 100 has mounting tables 120 on which the cassettes 20 having the substrates W received therein are placed. A plurality of mounting tables 120 are provided, and are disposed is along the second direction 14 in a row. In FIG. 1, four mounting tables 120 are provided.

The index module 200 transfers the substrates W between the cassettes 20 placed on the mounting tables 120 of the load port 100 and the first buffer module 300. The index module 200 has a frame 210, an index robot 220, and a guide rail 230. The frame 210 has a substantially rectangular parallelepiped shape with an empty space inside, and is disposed between the load port 100 and the first buffer module 300. The frame 210 of the index module 200 may have a height less than that of a frame 310 of the first buffer module 300 that will be described below. The index robot 220 and the guide rail 230 are disposed in the frame 210. The index robot 220 has a four-axis driven structure such that a hand 221 that directly handles a substrate W is movable and rotatable in the first direction 12, the second direction 14, and the third direction 16. The index robot 220 has the hand 221, an arm 222, a support rod 223, and a base 224. The hand 221 is fixedly installed in the arm 222. The arm 222 is provided in a retractable and rotatable structure. The support rod 223 is configured such that the lengthwise direction thereof is parallel to the third direction 16. The arm 222 is coupled to the support rod 223 to be movable along the support rod 223. The support rod 223 is fixedly coupled to the base 224. The guide rail 230 is provided such that the lengthwise direction thereof is parallel to the second direction 14. The base 224 is coupled to the guide rail 230 to be rectilinearly movable along the guide rail 230. Although not shown, the frame 210 is further provided with a door opener that opens and closes a door of the cassette 20.

The first buffer module 300 has a frame 310, a first buffer 320, a second buffer 330, a cooling chamber 350, and a first buffer robot 360. The frame 310 has a rectangular parallelepiped shape having an empty interior, and is disposed between the index module 200 and the coating and developing module 400. The first buffer 320, the second buffer 330, the cooling chamber 350, and the first buffer robot 360 are positioned within the frame 310. The cooling chamber 350, the second buffer 330, and the first buffer 320 are disposed along the third direction 16 sequentially from the bottom. The first buffer 320 is positioned at a height corresponding to a coating module 401 of the coating and developing module 400 that will be described below and the second buffer 330 and the cooling chamber 350 are positioned at a height corresponding to a developing module 402 of the coating and developing module 400 that will be described below. The first buffer robot 360 is spaced apart by a predetermined distance in the second direction 14 from the second buffer 330, the cooling chamber 350, and the first buffer 320.

The first buffer 320 and the second buffer 330 temporarily store a plurality of substrates W. The second buffer 330 has a housing 331 and a plurality of supports 332. The supports 332 are disposed within the housing 331, and are spaced apart from one another along the third direction 16. One substrate W is placed on each of the supports 332. The housing 331 has openings (not shown) that face the directions in which the index robot 220, the first buffer robot 360, and a developer robot 482 are provided, respectively, such that the index robot 220, the first buffer robot 360, and the developer robot 482 of the developing module 402, which will be described below, load the substrates W onto the supports 332 in the housing 331 or unload the substrates W from the supports 332 in the housing 331. The first buffer 320 has a structure that is substantially similar to that of the second buffer 330. Meanwhile, the housing 321 of the first buffer 320 has an opening that faces the direction in which the first buffer robot 360 is provided and the direction in which a coater robot 432 located in the coating module 401, which will be described below, is provided. The number of supports 322 provided in the first buffer 320 and the number of supports 332 provided in the second buffer 330 may be the same or different. According to an embodiment, the number of the supports 332 provided in the second buffer 330 may be greater than the number of the supports 332 provided in the first buffer 320.

The first buffer robot 360 transfers a substrate W between the first buffer 320 and the second buffer 330. The first buffer robot 360 has a hand 361, an arm 362, and a support rod 363. The hand 361 is fixedly installed in the arm 362. The arm 362 is provided in a retractable structure, allowing the hand 361 to be movable along the second direction 14. The arm 362 is coupled to the support rod 363 to be rectilinearly movable in the third direction 16 along the support rod 363. The support rod 363 has a length extending from a position corresponding to the second buffer 330 to a position corresponding to the first buffer 320. The support rod 363 may be provided to extend longer upwards or downwards. The first buffer robot 360 may be provided such that the hand 361 is simply two-axis driven along the second direction 14 and the third direction 16.

The cooling chamber 350 cools a substrate W. The cooling chamber 350 has a housing 351 and a cooling plate 352. The cooling plate 352 has a cooling means 353 that cools an upper surface thereof on which a substrate W is located and the substrate W. Various methods, such as cooling by cooling water, cooling by a thermoelectric element, and the like, may be used for the cooling means 353. A lift pin assembly (not shown) that locates a substrate W on the cooling plate 352 may be provided in the cooling chamber 350. The housing 351 has openings (not shown) that face the directions in which the index robot 220 and the developer robot 482 are provided, respectively, such that the index robot 220 and the developer robot 482 provided in the developing module 402 load the substrate W onto the cooling plate 352 or unload the substrate W from the cooling plate 352. In addition, the cooling chamber 350 may include doors (not shown) that open and close the openings described above.

The coating and developing module 400 performs a process of coating the substrate W with a photoresist before an exposing process and a developing process on the substrate W after the exposing process. The coating and developing module 400 has a substantially rectangular parallelepiped shape. The coating and developing module 400 has the coating module 401 and the developing module 402. The coating module 401 and the developing module 402 may be disposed to be partitioned from each other in different layers. According to an example, the coating module 401 is located above the development module 402.

The coating module 401 performs a process of coating the substrate W with a photosensitive liquid such as a photoresist and a heat treatment process, such as heating and cooling, on the substrate W before and after the resist coating process. The coating module 401 has a resist coating unit 410, a bake unit 420, and a transfer chamber 430. The resist coating unit 410, the bake unit 420, and the transfer chamber 430 are sequentially disposed along the second direction 14. Accordingly, the resist coating unit 410 and the bake unit 420 are spaced apart from each other in the second direction 14 with the transfer chamber 430 interposed therebetween. A plurality of resist coating unit 410 may be provided, and a plurality of resist coating units 410 may be provided in each of the first direction 12 and the third direction 16. The drawings illustrate an example that six resist coating units 410 are provided. The bake units 420 are arranged in each of the first direction 12 and the third direction 16. The drawings illustrate an example that six bake units 420 are provided. However, a larger or smaller number of bake units 420 may be provided.

The transfer chamber 430 is located side by side with the first buffer 320 of the first buffer module 300 in the first direction 12. The coater robot 432 and a guide rail 433 are located in the transfer chamber 430. The transfer chamber 430 has a substantially rectangular shape. The coater robot 432 transfers a substrate W between the bake units 420, the resist coating units 410, the first buffer 320 of the first buffer module 300, and a first cooling chamber 520 of the second buffer module 500, which will be described below. The guide rail 433 is disposed such that the lengthwise direction thereof is parallel to the first direction 12. The guide rail 433 guides the coater robot 432 to rectilinearly move in the first direction 12. The coater robot 432 has a hand 434, an arm 435, a support rod 436, and a base 437. The hand 434 is fixedly installed in the arm 435. The arm 435 is provided in a retractable structure, allowing the hand 434 to be horizontally movable. The support rod 436 is disposed such that the lengthwise direction thereof is parallel to the third direction 16. The arm 435 is coupled to the support rod 436 to be rectilinearly movable in the third direction 16 along the support rod 436. The support rod 436 is fixedly coupled to the base 437, and the base 437 is coupled to the guide rail 433 to be movable along the guide rail 433.

The resist coating units 410 all have the same structure. However, the types of photosensitive liquids used in the respective resist coating units 410 may differ from one another. For example, chemical amplification resist may be used as a photosensitive liquid. Each of the resist coating units 410 coats the substrate W with a photosensitive liquid. The resist coating unit 410 has a housing 411, a support plate 412, and a nozzle 413. The housing 411 has a cup shape with an open top. The support plate 412 is located in the housing 411 and supports the substrate W. The support plate 412 is rotatably provided. The nozzle 413 dispenses the photosensitive liquid onto the substrate W placed on the support plate 412. The nozzle 413 has a circular pipe shape, and may dispense the photosensitive liquid to the center of the substrate W. Optionally, the nozzle 413 may have a length corresponding to the diameter of the substrate W, and a dispensing hole of the nozzle 413 may have a slit shape. Additionally, the resist coating unit 410 may further include a nozzle 414 that dispenses a cleaning solution, such as deionized water, to clean the surface of the substrate W that is coated with the photosensitive liquid.

The bake unit 420 performs heat treatment on the substrate W. The bake unit 420 perform heat treatment on the substrate W before and after coating the substrate W with the photosensitive liquid. The bake unit 420 may heat the substrate W to a predetermined temperature to change the surface properties of the substrate W before coating the substrate W with the photosensitive liquid, and may form a film of a treatment liquid, such as an adhesive, on the substrate W. The bake unit 420 may perform heat treatment on a photosensitive liquid film on the substrate W coated with the photosensitive liquid in an atmosphere of reduced pressure. The bake unit 420 may volatilize a volatile material contained in the photosensitive liquid film. In the present embodiment, the bake is unit 420 is described as a unit for performing heat treatment on a photosensitive liquid film.

The bake unit 420 includes a cooling plate 422 and a heating unit 424. The cooling plate 422 cools the substrate W heated by the heating unit 424. The cooling plate 422 has a circular disk shape. The cooling plate 422 is provided with a cooling means, such as cooling water or a thermoelectric element. For example, the substrate W placed on the cooling plate 422 may be cooled to a temperature that is the same as, or close to, the room temperature.

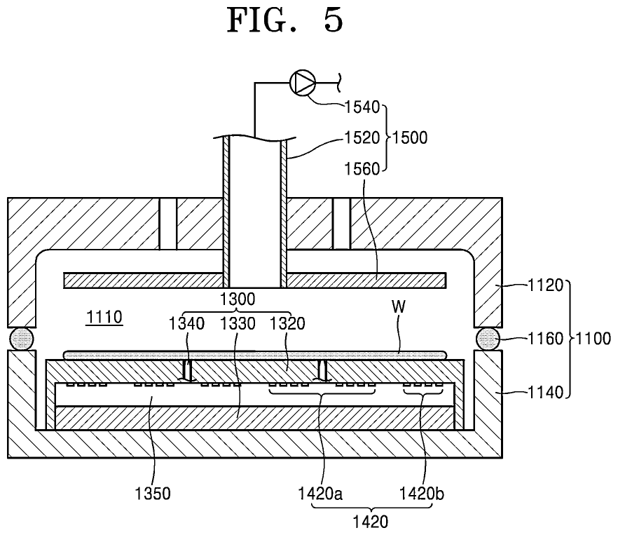

The heating unit 424 heats the substrate W in an atmospheric atmosphere or in an atmosphere of reduced pressure lower than the atmospheric pressure. The heating unit 424 is provided as a substrate treatment apparatus that performs heat treatment on the substrate W. FIG. is a cross-sectional view of an apparatus for treating a substrate that performs a function of the heating unit 424 of FIG. 1. Referring to FIG. 5, the apparatus for treating a substrate includes a process chamber 1100, an exhaust unit 1500, a substrate support member 1300, and a heater heating element 1420.

The process chamber 1100 provides a treatment space 1110 in the interior thereof, in which a process of heating the substrate W is performed. The treatment space 1110 is sealed from the outside. The process chamber 1100 includes an upper body 1120, a lower body 1140, and a sealing member 1160.

The upper body 1120 has a vessel shape that is open at the bottom. A central hole and peripheral holes are formed on an upper surface of the upper body 1120. The central hole is formed at the center of the upper body. The central hole functions as an exhaust hole through which the atmosphere of the treatment space is discharged. A plurality of peripheral holes are provided and formed at positions away from the center of the upper body. The peripheral holes function as inlet holes through which an external gaseous current enters into the treatment space 1110. The external gaseous current may be an inert gas. The peripheral holes are located to surround the central hole.

The lower body 1140 has a vessel shape that is open at the top. The lower body 1140 is located under the upper body 1120. The upper body 1120 and the lower body 1140 are located to face each other in a vertical direction. The upper body 1120 and the lower body 1140 are combined with each other to form the treatment space 1110 therebetween. The upper body 1120 and the lower body 1140 are located such that the central axes thereof coincide with each other with respect to the vertical direction. The lower body 1140 may have the same diameter as the upper body 1120. That is, an upper end of the lower body 1140 may be located to be opposite to a lower end of the upper body 1120.

The sealing member 1160 is located between the upper body 1120 and the lower body 1140. The sealing member 1160 seals the treatment space 1110 from the outside when the upper body 1120 and the lower body 1140 are brought into contact with each other. The sealing member 1160 may be an O-ring member 1160 having an annular ring shape. The sealing member 1160 may be fixedly coupled to the upper end of the lower body 1140.

The exhaust unit 1500 exhausts the atmosphere of the treatment space 1110. The exhaust unit 1500 includes an exhaust pipe 1520, a pressure-reducing member 1540, and a facing plate 1560. The exhaust pipe 1520 has a pipe shape with opposite ends open. The exhaust pipe 1520 is provided such that a lengthwise direction thereof faces the up-down direction. The exhaust pipe 1520 is fixedly coupled to the upper body 1120. The exhaust pipe 1520 is located to pass through the central hole 1122 of the upper body 1120. A lower region of the exhaust pipe 1520, which includes a lower end of the exhaust pipe 1520, is located in the treatment space 1110, and an upper region of an exhaust pipe 1520, which includes an upper end of the exhaust pipe 1520, is located outside the treatment space 1110. That is, the upper end of the exhaust pipe 1520 is located to be higher than the upper body 1120. The exhaust pipe 1520 is connected to the pressure-reducing member 1540. The pressure-reducing member 1540 reduces a pressure of the exhaust pipe 1520. Accordingly, the atmosphere of the treatment space 1110 may be exhausted through the exhaust pipe 1520.

The facing plate 1560 guides a flow direction of the gaseous current introduced into the treatment space 1110. The facing plate 1560 guides a flow direction of the gaseous current in the treatment space 1110. The facing plate 1560 is located above the support plate 1320 in the treatment space 1110. The facing plate 1560 is located at a height corresponding to the upper body 1120. The facing plate 1560 is located to face the support plate 1320. The facing plate 1560 is fixedly coupled to the lower end of the exhaust pipe 1520. The facing plate 1560 is provided to have an outer diameter that is smaller than the inner diameter of the upper body 1120. Accordingly, an aperture is formed between a side end of the facing plate 1560 and an inner surface of the upper body 1120. A flow direction of the gaseous current introduce into the treatment space 1110 is guided by the facing plate 1560, and the current is supplied through the aperture.

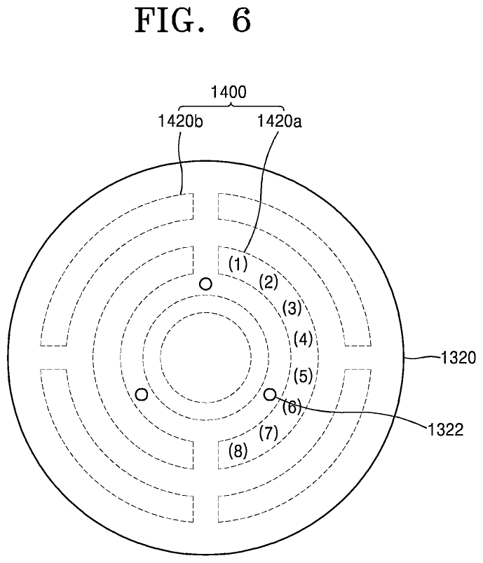

Referring to FIGS. 5 and 6, the substrate support member 1300 supports the substrate W in the treatment space 1110. The substrate support member 1300 includes a first support plate 1320, a second support plate 1330, and a lift pin 1340. The second support plate 1330 is fixedly coupled to the lower body 1140. The first support plate 1320 and the second support plate 1330 are coupled to each other to form a support plate. The first support plate 1320 and the second support plate 1330 have a circular disk-shaped cross section. An upper surface of the first support plate 1320 is provided as a seating surface on which the substrate W is seated. A central region of the upper surface of the support plate 1320, which includes the center of the upper surface of the support plate 1320, functions as a seating surface on which the substrate W is seated. That is, the upper surface of the support plate 1320 has a diameter that is larger than the substrate W. A plurality of pin holes 1322 are formed on the seating surface of the support plate 1320. When viewed from the top, the pin holes 1322 are arranged to surround the center axis of the first support plate 1320. The is pin holes 1322 are arranged to be spaced apart from one another along a circumferential direction.

The pin holes 1322 are space apart from one another at the same interval. A lift pin 1340 is provided in each of the pin holes 1322. The lift pin 1340 is provided to move vertically. The lift pin 1340 raises the substrate W from the seating surface, or seats the substrate W on the seating surface. For example, three pin holes 1322 may be provided. The first support plate 1320 and the second support plate 1330 may be formed of a material including nitride aluminum (AlN).

The heater heating element 1420 is a structure that generates heat for heat treatment on the substrate W seated on the seating surface of the first support plate 1320. For example, the heater heating element 1420 may be a thermoelectric element structure or a heating wire structure that generates heat using electrical resistance, and may heat the substrate W placed on the first support plate 1320. Heat generated by the heater heating element 1420 is transferred to the substrate W through the first support plate 1320 and thus the first support plate 1320 and the heater heating element 1420 may be understood as heaters that heat the substrate W. The heater heating element 1420 may be installed on a surface opposite to the seating surface of the first support plate 1320. The heater heating element 1420 may be located in a separation space 1350 between the first support plate 1320 and the second support plate 1330. In some cases, the first support plate 1320 and the second support plate 1330 may be arranged so close to each other that the separation space 1350 is hardly formed. Therefore, it may be construed that the heater heating element 1420 is provided in the interior of the support plate.

In order to improve temperature distribution uniformity of the substrate W, the heater heating element 1420 may include a first heater heating element 1420a and a second heater heating element 1420b that is separate from the first heater heating element 1420a. The first heater heating element 1420a and the second heater heating element 1420b are installed on the surface opposite to the seating surface. The first heater heating element 1420a and the second heater heating element 1420b are located on the same plane. The first heater heating element 1420a and the second heater heating element 1420b heat different regions of the first support plate 1320. When viewed from the top, the first heater heating element 1420a may be located at the central area of the first support plate 1320 and the second heater heating element 1420b may be located at the edge area of the first support plate 1320. The regions of the first support plate 1320 that correspond to each of the first heater heating element 1420a and the second heater heating element 1420b are provided as heating zones. The temperatures of the heater heating elements 1420a and 1420b may be independently adjusted. For example, fifteen heating zones may be provided. The temperatures of the heating zones are measured by sensors (not shown).

The heater heating element 1420 may be implemented using, for example, a printed circuit sintering process. That is, a pattern is printed using ink having particles in an emulsion state and heat is applied to the printed ink pattern to cause a plurality of particles contained in the ink to melt and thermally fuse together, so that the sintered heater heating element 1420 may be implemented on the first support plate 1320. In order to minimize a temperature deviation of each of the heater heating elements 1420a and 1420b, it is necessary to attain a uniform amount of heat by adjusting, such as increasing or decreasing, the electrical resistance value of each of the heater heating elements 1420a and 1420b.

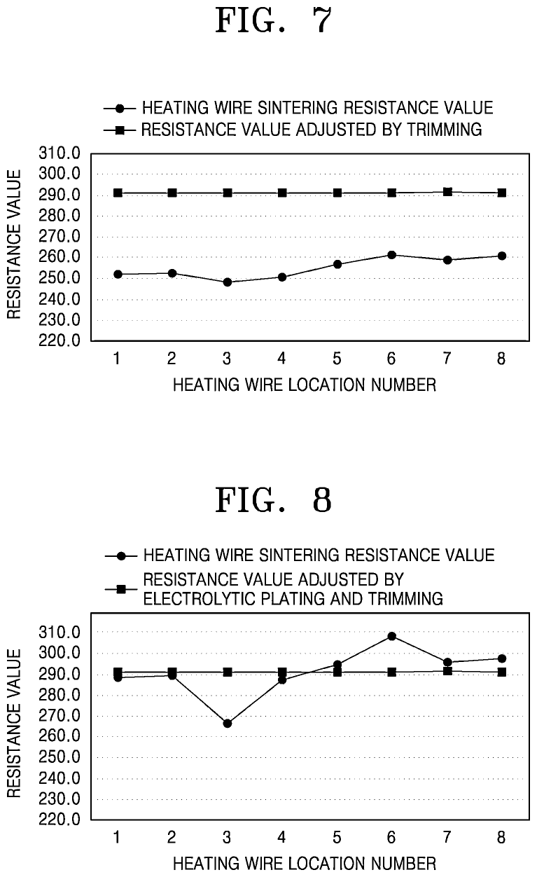

Referring to FIGS. 6 and 7, a heating wire sintering resistance value may be measured according to locations 1 to 8 of the heater heating element 1420. Heating wire location numbers of FIG. 7 correspond to locations 1 to 8 shown in FIG. 6. If the measured heating wire sintering electrical resistance value is lower than a target resistance value, a trimming process may be performed on the corresponding heater heating element 1420 to increase the electrical resistance value. For example, by performing the trimming process, a groove may be formed on an upper is surface of the heater heating element 1420, or a portion of the heater heating element 1420 may be removed so that the width of the upper surface or a side surface of the heater heating element 1420 is reduced.

The trimming process may include, for example, a laser trimming process. The laser trimming process includes a process of removing a portion of the heater heating element 1420 or changing physical properties of the heater heating element 1420 by emitting laser light to the heater heating element 1420. For example, by performing the laser trimming process, a groove may be formed on an upper surface of the heater heating element 1420, or a portion of the upper surface or a side surface of the heater heating element 1420 may be removed so that the width of the upper surface or the side surface is reduced. Alternatively, by performing the laser trimming process, the physical properties of the material constituting the heater heating element 1420 are changed so that the electrical resistance value may change. Although the laser trimming process is described as the trimming process, the technical idea of the present disclosure is not limited thereto, and a trimming process using another process may be used.

Referring to FIG. 7, it is confirmed that a resistance value of the heater heating element 1420 before applying the laser trimming process is at a level of approximately 250 to 260 whereas the resistance value of the heater heating element 1420 after applying the laser trimming process is increased to a level of 290. However, when the heating wire sintering electrical resistance value is higher than a target resistance value, there is a problem in that the electrical resistance value cannot be lowered by performing a laser trimming process. In this case, the heater heating element 1420 has to be re-manufactured, which inevitably leads to a decrease in productivity.

According to an embodiment of the present disclosure, when the heating wire sintering electrical resistance value is higher than a target resistance value, a process of forming a resistance adjusting material layer on the heater heating element 1420 is introduced instead of the trimming process. The process of forming the resistance adjusting material layer may include, for example, a plating process, a deposition process, or a printing process. The plating process may include an electrolytic plating process or an electroless plating process. The deposition process may be a chemical vapor deposition (CVD) process, a physical vapor deposition (PVD) process, or an atomic layer deposition (ALD) process. The resistance adjusting material layer may be a material layer made of the same material as the material constituting the heater heating element 1420 or a material layer including at least some elements of a compound constituting the heater heating element 1420.

A process of forming the resistance adjusting material layer may be performed, for example, after the heater heating element 1420 is formed on the first support plate 1320 and before the first support plate 1320 and the second support plate 1330 are coupled to each other.

According to an embodiment of the present disclosure, the resistance value of the heater heating element may be adjusted to a low level using the resistance adjusting material layer formed through electrolytic plating or may be adjusted to a high level using laser trimming. Accordingly, a resistance value adjustment time may be reduced by adjusting afterwards the heating wire sintering electrical resistance to approximate to the target resistance value, and a drawback of having to re-manufacturing the heater heating element in the case where the heating wire sintering electrical resistance value is higher than the target resistance value may be overcome.

Referring to FIGS. 6 and 8, the heating wire sintering resistance values according to locations 1 to 8 of the heater heating element 1420 may be in the range of 260 to 310. Heating wire location numbers of FIG. 8 correspond to locations 1 to 8 shown in FIG. 6. Assuming that a target resistance value is at a level of 290, a region corresponding to location 3 of the heater heating is element 1420 has a heating wire sintering resistance value lower than the target resistance value and a region corresponding to location 6 of the heater heating element 1420 has a heating wire sintering resistance value higher than the target resistance value. In this case, the resistance value of the region corresponding to location 3 of the heater heating element 1420 may be increased by selectively performing a laser trimming process and the resistance value of the region corresponding to location 6 of the heater heating element 1420 may be decreased, so that a uniform resistance value over the entire heater heating element 1420 may be achieved.

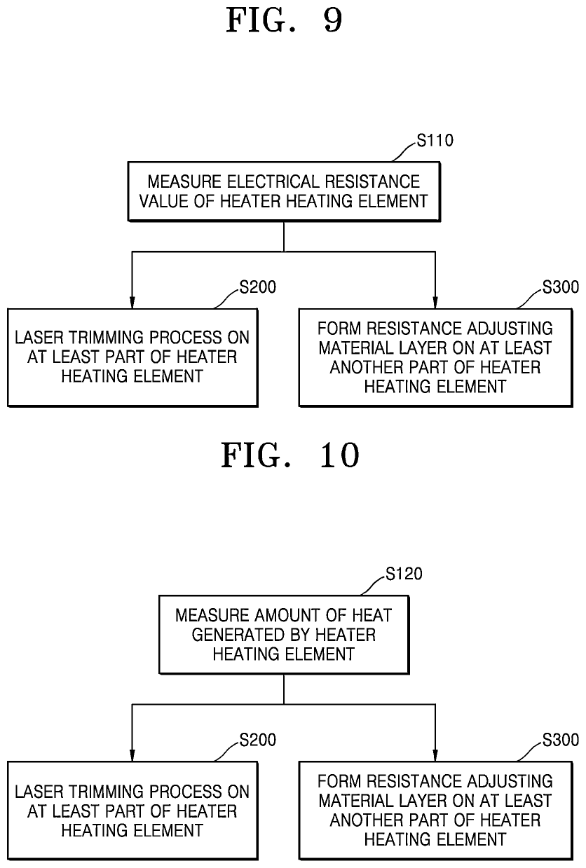

Referring to FIG. 9, a method of manufacturing a heater according to an embodiment of the present disclosure includes performing a laser trimming process on at least a part of a heater heating element for heating a substrate (S200); and forming a resistance adjusting material layer on at least another part of the heater heating element (S300).

In the method of manufacturing a heater according to an embodiment of the present disclosure, before performing the laser trimming process (S200) and forming the resistance adjusting material layer (S300), measuring an electrical resistance value of the heater heating element (S110) may be performed, and thereafter, performing the laser trimming process (S200) and forming the resistance adjusting material layer (S300) may be selectively performed on the basis of the electrical resistance value. An electrical resistance value of a first region (e.g., location 3 of FIG. 8) that is at least a part of the heater heating element to which the laser trimming process is to be applied may be relatively lower than an electrical resistance value of a second region (e.g., location 6 of FIG. 8) that is at least another part of the heater heating element on which the resistance adjusting material layer is to be formed. The electrical resistance value of the first region that is at least a part of the heater heating element is increased by performing the laser trimming process, and the electrical resistance value of the second region that is at least another part of the is heater heating element may be decreased by forming the resistance adjusting material layer.

Referring to FIG. 10, the method of manufacturing a heater according to another embodiment of the present disclosure includes performing a laser trimming process on at least a part of a heater heating element for heating a substrate (S200); and forming a resistance adjusting material layer on at least another part of the heater heating element (S300).

In the method of manufacturing a heater according to another embodiment of the present disclosure, before performing the laser trimming process (S200) and forming the resistance adjusting material layer (S300), measuring an amount of heat generated by the heater heating element (S110) may be performed, and thereafter, performing the laser trimming process (S200) and forming the resistance adjusting material layer (S300) may be performed on the basis of the amount of heat generated. In the measuring of the amount of heat generated by the heater (S110), the amount of heat generated may be measured using a thermal imaging camera. The amount of heat generated in the first region that is at least a part of the heater heating element to which the laser trimming process is to be applied may be relatively lower than the amount of heat generated in the second region that is at least another part of the heater heating element on which the resistance adjusting material layer is to be formed. The amount of heat generated in the first region that is at least a part of the heater heating element is increased by performing the laser trimming process, and the amount of heat generated in the second region that is at least another part of the heater heating element may be decreased by forming the resistance adjusting material layer.

Referring back to FIGS. 1 to 4, the developing module 402 may perform a developing process of removing a part of a photoresist by dispensing a developing solution to obtain a pattern on the substrate W and a heat treatment process, such as heating and cooling, on the substrate W before and after the developing process. The developing module 402 has a developing unit 460, a bake unit 479, and a transfer chamber 480. The developing unit 460, the bake unit 470, and the is transfer chamber 480 are sequentially disposed along the second direction 14. Accordingly, the developing unit 460 and the bake unit 470 are spaced apart from each other in the second direction 14 with the transfer chamber 480 interposed therebetween. A plurality of developing units 460 may be provided, and a plurality of developing units 460 may be provided in each of the first direction 12 and the third direction 16. The drawings illustrate an example that six developing units 460 are provided. The bake units 470 are arranged in each of the first direction 12 and the third direction 16. The drawings illustrate an example that six bake units 470 are provided. However, a larger or smaller number of bake units 470 may be provided.

The transfer chamber 480 is located side by side with the first buffer 330 of the first buffer module 300 in the first direction 12. The developer robot 482 and a guide rail 483 are located in the transfer chamber 480. The transfer chamber 480 has a substantially rectangular shape. The developer robot 482 transfers a substrate W between the bake units 470, the developing units 460, the second buffer 330 and the cooling chamber 350 of the first buffer module 300, and a second cooling chamber 540 of the second buffer module 500 that will be described below. The guide rail 483 is disposed such that the lengthwise direction thereof is parallel to the first direction 12. The guide rail 483 guides the developer robot 482 to rectilinearly move in the first direction 12. The developer robot 482 has a hand 484, an arm 485, a support rod 486, and a base 487. The hand 484 is fixedly installed in the arm 485. The arm 485 is provided in a retractable structure, allowing the hand 484 to be horizontally movable. The support rod 486 is disposed such that the lengthwise direction thereof is parallel to the third direction 16. The arm 485 is coupled to the support rod 486 to be rectilinearly movable in the third direction 16 along the support rod 486. The support rod 486 is fixedly coupled to the base 487. The base 487 is coupled to the guide rail 483 to be rectilinearly movable along the guide rail 483.

The developing units 460 all have the same structure. However, the types of developing is solutions used in the respective developing units 460 may differ from one another. Each of the developing units 460 removes light-irradiated regions of the photoresist on the substrate W. At this time, light-irradiated regions of a protective film are also removed. Selectively, depending on the type of photoresist used, only regions of the photoresist and the protective film that are not irradiated with light may be removed.

The developing unit 460 has a housing 461, a support plate 462, and a nozzle 463. The housing 461 has a cup shape with an open top. The support plate 462 is located in the housing 461 and supports the substrate W. The support plate 462 is rotatably provided. The nozzle 463 dispenses a developing solution onto the substrate W placed on the support plate 462. The nozzle 463 may have a circular tubular shape and may dispense the developing solution onto the center of the substrate W. Optionally, the nozzle 463 may have a length corresponding to the diameter of the substrate W, and a dispensing hole of the nozzle 463 may have a slit shape. Additionally, the developing unit 460 may further include a nozzle 464 that dispenses a cleaning solution such as deionized water to clean the surface of the substrate W onto which the developing solution is dispensed.

The bake units 470 of the developing module 402 performs heat treatment on the substrate W. For example, the bake units 470 perform a post bake process of heating the substrate W before the developing process, a hard bake process of heating the substrate W after the developing process, and a cooling process of cooling the substrate W after the bake processes. Each of the bake units 470 has a cooling plate 471 or a heating unit 472. The cooling plate 471 is provided with a cooling means 473, such as cooling water or a thermoelectric element. Alternatively, the heating plate 472 is provided with a heating means 474, such as a heating wire or a thermoelectric element. The heating means 474 may be, for example, the heater heating element described above. The cooling plate 471 and the heating unit 472 may be provided in one bake unit 470. Optionally, some bake is units 470 may include only the cooling plate 471, and the other bake units 470 may include only the heating unit 472. The bake units 470 of the developing module 402 have the same configuration as the bake units 402 of the coating module 401, and therefore detailed description thereof will be omitted. For example, the description of the heater heating element constituting the bake unit 470 of the developing module 402 will be replaced with the description of the heater heating element constituting the bake unit 420 of the coating module 401 described above.

The second buffer module 500 serves as a passage through which the substrate W is carried between the coating and developing module 400 and the pre/post-exposure treatment module 600. In addition, the second buffer module 500 performs a predetermined process, such as a cooling process or an edge exposing process, on the substrate W. The second buffer module 500 has a frame 510, a buffer 520, a first cooling chamber 530, a second cooling chamber 540, an edge exposing chamber 550, and a second buffer robot 560. The chamber 510 has a rectangular parallelepiped shape. The buffer 520, the first cooling chamber 530, the second cooling chamber 540, the edge exposing chamber 550, and the second buffer robot 560 are located in the frame 510. The buffer 520, the first cooling chamber 530, and the edge exposing chamber 550 are disposed at the height corresponding to the coating module 401. The second cooling chamber 540 is disposed at the height corresponding to the developing module 402. The buffer 520, the first cooling chamber 530, and the second cooling chamber 540 are sequentially disposed in a row along the third direction 16. When viewed from the top, the buffer 520 is disposed side by side with the transfer chamber 430 of the coating module 401 along the first direction 12. The edge exposing chamber 550 is disposed to be spaced apart from the buffer 520 or the first cooling chamber 530 by a predetermined distance in the second direction 14.

The second buffer robot 560 carries the substrate W between the buffer 520, the first cooling chamber 530, and the edge exposing chamber 550. The second buffer robot 560 is located is between the edge exposing chamber 550 and the buffer 520. The second buffer robot 560 may have a structure similar to that of the first buffer robot 360. The first cooling chamber 530 and the edge exposing chamber 550 perform subsequent processes on the substrate W treated in the coating module 401. The first cooling chamber 530 cools the substrate W treated in the coating module 401. The first cooling chamber 530 has a structure similar to that of the cooling chamber 350 of the first buffer module 300. The edge exposing chamber 550 performs an edge exposing process on the substrate W subjected to the cooling process in the first cooling chamber 530. The buffer 520 temporarily stores the substrate W before the substrate W treated in the edge exposing chamber 550 is carried to a pre-treatment module 601 that will be described below. The second cooling chamber 540 cools the substrate W before the substrate W treated in a post-treatment module 602, which will be described below, is carried to the developing module 402. The second buffer module 500 may further include an additional buffer at the height corresponding to the developing module 402. In this case, the substrate W treated in the post-treatment module 602 may be carried to the developing module 402 after temporarily stored in the additional buffer.

In a case where an exposure apparatus 900 performs a liquid immersion lithography process, the pre/post-exposure treatment module 600 may perform a process of coating the substrate W with a protective film that protects the photoresist film coated on the substrate W during the liquid immersion lithography process. In addition, the pre/post-exposure treatment module 600 may perform a process of cleaning the substrate W after an exposing process. Further, in a case where a coating process is performed using chemical amplification resist, the pre/post-exposure treatment module 600 may perform a post-exposure bake process

The pre/post-exposure treatment module 600 has the pre-treatment module 601 and the post-treatment module 602. The pre-treatment module 601 performs a process of treating the substrate W before the exposing process, and the post-treatment module 602 performs a process is of treating the substrate W after the exposing process. The pre-treatment module 601 and the post-treatment module 602 are disposed to be partitioned from each other in different layers. According to an embodiment, the pre-treatment module 601 is located above the post-treatment module 602. The pre-treatment module 601 is located at the same height as the coating module 401. The post-treatment module 602 is located at the same height as the developing module 402. The pre-treatment module 601 has protective-film coating units 610, bake units 620, and a transfer chamber 630. The protective-film coating units 610, the transfer chamber 630, and the bake units 620 are sequentially disposed along the second direction 14. Accordingly, the protective-film coating units 610 and the bake units 620 are spaced apart from each other in the second direction 14 with the transfer chamber 630 interposed therebetween. The protective-film coating units 610 are arranged along the third direction 16 to form different layers. Selectively, the protective-film coating units 610 may be arranged in each of the first direction 12 and the third direction 16. The bake units 620 are arranged along the third direction 16 to form different layers. Selectively, the bake units 620 may be arranged in each of the first direction 12 and the third direction 16.

The transfer chamber 630 is located side by side with the first cooling chamber 530 of the second buffer module 500 in the first direction 12. A pre-treatment robot 632 is located in the transfer chamber 630. The transfer chamber 630 has a substantially square or rectangular shape. The pre-treatment robot 632 transfers the substrate W between the protective-film coating units 610, the bake units 620, the buffer 520 of the second buffer module 500, and a first buffer 720 of the interface module 700 that will be described below. The pre-treatment robot 632 has a hand 633, an arm 634, and a support rod 635. The hand 633 is fixedly installed in the arm 634. The arm 634 is provided in a retractable and rotatable structure. The arm 634 is coupled to the support rod 635 to be rectilinearly movable in the third direction 16 along the support rod 635.

Each of the protective-film coating units 610 coats the substrate W with a protective film is that protects a resist film during the liquid immersion lithography. The protective-film coating unit 610 has a housing 611, a support plate 612, and a nozzle 613. The housing 611 has a cup shape with an open top. The support plate 612 is located in the housing 611 and supports the substrate W. The support plate 612 is rotatably provided. The nozzle 613 dispenses a protective liquid for forming a protective film onto the substrate W placed on the support plate 612. The nozzle 613 may have a circular tubular shape and may dispense the protective liquid onto the center of the substrate W. Optionally, the nozzle 613 may have a length corresponding to the diameter of the substrate W, and a dispensing hole of the nozzle 613 may have a slit shape. In this case, the support plate 612 may be provided in a fixed state. The protective liquid contains a foam material. A material having a low affinity with photoresist and water may be used as the protective liquid. For example, the protective liquid may include a fluorine-based solvent. The protective-film coating unit 610 dispenses the protective liquid onto the central region of the substrate W while rotating the substrate W placed on the support plate 612.

Each of the bake units 620 performs heat treatment on the substrate W coated with the protective film. The bake unit 620 has a cooling plate 621 or a heating plate 622. The cooling plate 621 is provided with a cooling means 623, such as cooling water or a thermoelectric element. Alternatively, the heating plate 622 is provided with a heating means 624, such as a heating wire or a thermoelectric element. The heating means 624 may be, for example, the heater heating element described above. The heating plate 622 and the cooling plate 621 may be provided in one bake unit 620. Optionally, some bake units 620 may include only the heating plate 622, and the other bake units 620 may include only the cooling plate 621.

The bake units 620 of the pre-treatment module 601 have the same configuration as the bake units 420 of the coating module 401, and therefore detailed description thereof will be omitted. For example, the description of the heater heating element constituting the bake unit 620 of the pre-treatment module 601 will be replaced with the description of the heater heating element constituting the bake unit 420 of the coating module 401 described above.

The post-treatment module 602 has cleaning chambers 660, post-exposure bake units 670, and a transfer chamber 680. The cleaning chambers 660, the transfer chamber 680, and the post-exposure bake units 670 are sequentially disposed along the second direction 14. Accordingly, the cleaning chambers 660 and the post-exposure bake units 670 are spaced apart from each other in the second direction 14 with the transfer chamber 680 interposed therebetween. The cleaning chambers 660 are arranged along the third direction 16 to form different layers. Selectively, the cleaning chambers 660 may be arranged in each of the first direction 12 and the third direction 16. The post-exposure bake units 670 are arranged along the third direction 16 to form different layers. Selectively, the post-exposure bake units 670 may be arranged in each of the first direction 12 and the third direction 16.

The transfer chamber 680, when viewed from the top, is located side by side with the first cooling chamber 540 of the second buffer module 500 in the first direction 12. The transfer chamber 680 has a substantially square or rectangular shape. A post-treatment robot 682 is located in the transfer chamber 680. The post-treatment robot 682 transfers the substrate W between the cleaning chambers 660, the post-exposure bake units 670, the second cooling chamber 540 of the second buffer module 500, and a second buffer 730 of the interface module 700 that will be described below. The post-treatment robot 682 provided in the post-treatment module 602 may have the same structure as the pre-treatment robot 632 provided in the pre-treatment module 601.

Each of the cleaning chambers 660 performs a cleaning process on the substrate W after the exposing process. The cleaning chamber 660 has a housing 661, a support plate 662, and a nozzle 663. The housing 661 has a cup shape with an open top. The support plate 662 is located in the housing 661 and supports the substrate W. The support plate 662 is rotatably provided. The is nozzle 663 dispenses a cleaning solution onto the substrate W placed on the support plate 662. Water such as deionized water may be used as the cleaning solution. The cleaning chamber 660 dispenses the cleaning solution onto the central region of the substrate W while rotating the substrate W placed on the support plate 662. Optionally, while the substrate W is rotated, the nozzle 663 may rectilinearly or rotationally move from the central region of the substrate W to the peripheral region thereof.

Each of the post-exposure bake units 670 heats the substrate W, which is subjected to the exposing process, by using far ultraviolet rays. A post-exposure bake process heats the substrate W to amplify acid generated in the photoresist by the exposing process, thereby completing a change in the property of the photoresist. The post-exposure bake unit 670 has a heating plate 672.

The heating plate 672 is provided with a heating means 674, such as a heating wire or a thermoelectric element. The heating means 674 may be, for example, the heater heating element described above. The post-exposure bake unit 670 may further include a cooling plate 671 therein. The cooling plate 671 is provided with a cooling means 673, such as cooling water or a thermoelectric element. Optionally, a bake unit having only the cooling plate 671 may be additionally provided.

The bake units 670 of the post-treatment module 602 have the same configuration as the bake units 420 of the coating module 401, and therefore detailed description thereof will be omitted. For example, the description of the heater heating element constituting the bake unit 670 of the post-treatment module 602 will be replaced with the description of the heater heating element constituting the bake unit 420 of the coating module 401 described above.

As described above, the pre-treatment module 601 and the post-treatment module 602 are completely separated from each other in the pre/post-exposure treatment module 600. In addition, the transfer chamber 630 of the pre-treatment module 601 and the transfer chamber 680 of the is post-treatment module 602 may have the same size and may completely overlap each other when viewed from the top. Moreover, the protective-film coating unit 610 and the cleaning chamber 660 may have the same size and may completely overlap each other when viewed from the top. In addition, the bake unit 620 and the post-exposure bake unit 670 may have the same size and may completely overlap each other when viewed from the top.

The interface module 700 transfers the substrate W between the pre/post-exposure treatment module 600 and the exposure apparatus 900. The interface module 700 has a frame 710, the first buffer 720, the second buffer 730, and an interface robot 740. The first buffer 720, the second buffer 730, and the interface robot 740 are located in the frame 710. The first buffer 720 and the second buffer 730 are spaced apart from each other by a predetermined distance and stacked atop each other. The first buffer 720 is disposed in a higher position than the second buffer 730. The first buffer 720 is located at the height corresponding to the pre-treatment module 601, and the second buffer 730 is disposed at the height corresponding to the post-treatment module 602. When viewed from the top, the first buffer 720 is disposed in a row along the first direction 12 together with the transfer chamber 630 of the pre-treatment module 601, and the second buffer 730 is disposed in a row along the first direction 12 together with the transfer chamber 680 of the post-treatment module 602.

The interface robot 740 is located to be spaced apart from the first buffer 720 and the second buffer 730 in the second direction 14. The interface robot 740 transfers the substrate W between the first buffer 720, the second buffer 730, and the exposure apparatus 900. The interface robot 740 has a structure substantially similar to that of the second buffer robot 560.

The first buffer 720 temporarily stores the substrate W before the substrate W treated in the pre-treatment module 601 is moved to the exposure apparatus 900. The second buffer 730 temporarily stores the substrate W before the substrate W treated in the exposure apparatus 900 is is moved to the post-treatment module 602. The second buffer 720 has a housing 721 and a plurality of supports 722. The supports 722 are disposed within the housing 721, and are spaced apart from one another along the third direction 16. One substrate W is placed on each of the supports 722. The housing 721 has openings (not shown) that face the directions in which the interface robot 740 and the pre-treatment robot 632 are provided, respectively, such that the interface robot 740 and the pre-treatment robot 632 load the substrates W onto the supports 722 in the housing 721 or unload the substrates W from the supports 722 in the housing 721. The first buffer 730 has a structure that is substantially similar to that of the second buffer 720. However, a housing 4531 of the second buffer 730 has an opening in the direction in which the interface robot 740 and the post-treatment robot 682 are provided. The interface module 700 may include only the buffers and the robot as described above, without including a chamber for performing a predetermined process on a substrate.

The heater and the method for manufacturing the same according to the technical idea of the present disclosure described so far may be applied to a substrate treatment apparatus that performs a deposition process or an etching process as well as a substrate treatment apparatus that performs a photolithography process.

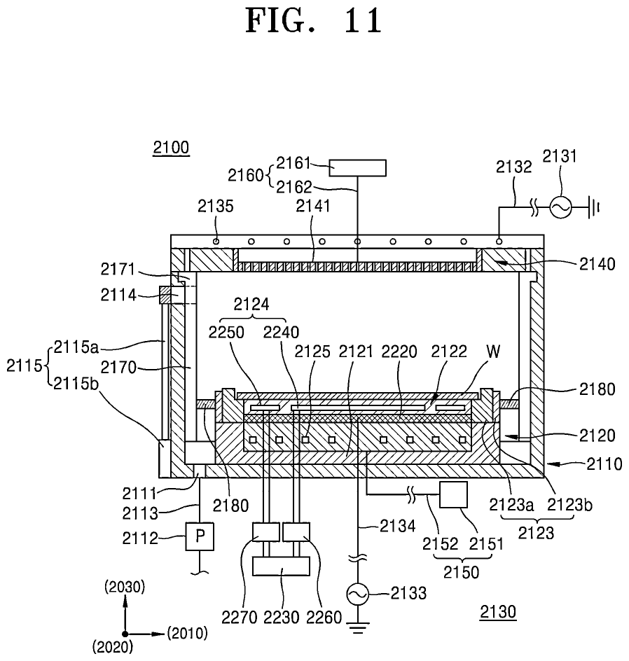

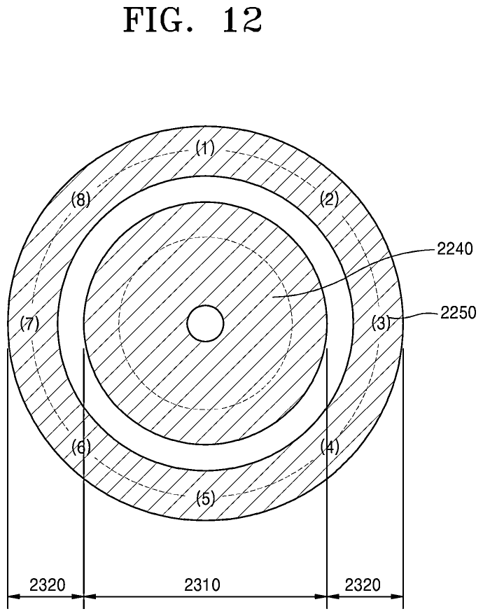

Referring to FIGS. 11 and 12, an apparatus for treating a substrate may be configured to include a process chamber 2110 capable of accommodating a substrate, a support member 2120 configured to support the substrate, a plasma generation unit 2130, and a shower head unit 2140, a first gas supply unit 2150, a second gas supply unit 2160, a liner 2170, and a baffle unit 2180.

The apparatus 2100 for treating a substrate is a system that treats a substrate W using a dry etching process. The apparatus 2100 for treating a substrate may treat the substrate W using, for example, a plasma process.

The process chamber 2110 provides a space in which a plasma process is performed. The is process chamber 2110 may be provided with an exhaust hole 2111 at a lower portion thereof. The exhaust hole 2111 may be connected to an exhaust line 2113 on which a pump 2112 is mounted. The exhaust hole 2111 may discharge a reaction-by-product generated during a plasma process and a gas remaining in the process chamber 2110 to the outside of the process chamber 2110 through the exhaust line 2113. In this case, the internal space of the process chamber 2110 may be decompressed to a predetermined pressure.

The process chamber 2110 may have an opening 2114 formed on a sidewall thereof. The opening 2114 may function as a passage through which the substrate W enters and exits the process chamber 2110. The opening 2114 may be configured to be opened and closed by a door assembly 2115.

The door assembly 2115 may include an outer door 2115a and a door driving unit 2115b. The outer door 2115a is provided on the outer wall of the process chamber 2110. The outer door 2115a may be moved in the vertical direction (i.e., the third direction 30) through the door driving unit 2115b. The door driving unit 2115b may be operated using a motor, a hydraulic cylinder, a pneumatic cylinder, or the like.

The support member 2120 may be installed in an inner lower region of the process chamber 2110. The support member 2120 may support the substrate W using an electrostatic force. However, the present embodiment is not limited thereto. The support member 2120 may support the substrate W in various ways such as mechanical clamping, vacuum, and the like. In a case where the substrate W is supported by using an electrostatic force, the support member 2120 may be configured to include a base 2121, an electrostatic chuck (ESC) 2122, a ring assembly 2123, a heating member 2124, and a cooling member 2125.

The electrostatic chuck 2122 supports the substrate W seated thereon by using an electrostatic force. The electrostatic chuck 2122 may be made of a ceramic material, and may be is coupled to the base 2121 to be fixed on the base 2121.

The electrostatic chuck 2122 may control the gradient between a center region and an edge region of the substrate W by adjusting the impedances of center and edge electrodes constituting a lower electrode inside the process chamber 2110. Meanwhile, the electrostatic chuck 2122 may be mounted movable in the vertical direction (i.e., third direction 2030) inside the process chamber 2110 by means of a driving member (not shown). In the case where the electrostatic chuck 2122 is mounted movable in the vertical direction, it may be possible to locate the substrate W at a position at which the plasma distribution is more uniform.

The ring assembly 2123 may be arranged to surround the edge of the electrostatic chuck 2122. The ring assembly 2123 has a ring shape and may be configured to support the edge region of the substrate W. The ring assembly 2123 may include a focus ring 2123a and an insulation ring 2123b.

The focus ring 2123a may be arranged inside the insulation ring 2123b to surround the electrostatic chuck 2122. The focus ring 2123a may be made of a silicon material and may concentrate plasma on the substrate W. The insulation ring 2123b may be arranged outside the focus ring 2123a to surround the focus ring 2123a. The insulation ring 2123b may be made of a quartz material. Meanwhile, the ring assembly 2123 may further include an edge ring that is tightly adjoined to the edge of the focus ring 2123a. The edge ring may be formed to prevent the side surface of the electrostatic chuck 2122 from being damaged by the plasma.

The heating member 2124 and the cooling member 2125 may be provided for the substrate W to maintain a process temperature during an etching process in the process chamber 2110. For this purpose, the heating member 2124 may be provided in the form of a heating wire, and the cooling member 2125 may be provided in the form of a cooling line in which a refrigerant is flowing.

The heating member 2124 and the cooling member 2125 may be installed inside the support member 2120 in order for the substrate W to maintain the process temperature. For example, the heating member 2124 may be installed in the interior of the electrostatic chuck 2122, and the cooling member 2125 may be installed in the interior of the base 2121.

The first gas supply unit 2150 may supply gas for removing foreign substances remaining on the top of the ring assembly 2123 or around the edge of the electrostatic chuck 2122. The first gas supply unit 2150 may include a first gas supply source 2151 and a first gas supply line 2152.

The plasma generation unit 2130 may generate plasma with the gas remaining in a discharging space. Here, the discharging space may mean a space located above the support member 2120 in the inner space of the process chamber 2110. The plasma generation unit 2130 may generate plasma in the discharging space inside the process chamber 2110 using an inductively coupled plasma (ICP) source. In this case, the plasma generation unit 2130 may use an antenna 2135 mounted on an upper portion of the process chamber 2110 as an upper electrode and the electrostatic chuck 2122 as a lower electrode. However, the present embodiment is not limited thereto. The plasma generation unit 2130 may also generate plasma in the discharging space inside the process chamber 2110 using a capacitively coupled plasma (CCP) source. In this case, the plasma generation unit 2130 may use the shower head unit 2140 installed inside the process chamber 2110 as the upper electrode and the electrostatic chuck 122 as the lower electrode.

The plasma generation unit 2130 may be configured to include the upper electrode, the lower electrode, an upper power source 2131, and a lower power source 2133. The upper power source 2131 may apply power to the upper electrode. The upper power source 2131 may act as a plasma source for generating plasma and control the characteristics of the plasma in cooperation with the lower power source 2133.

The lower power source 2133 may apply power to the lower electrode. The lower power is source 2133 may produce a sheath voltage so that ions collide with the substrate W, resulting in the improvement of anisotropic etching.

The electrostatic chuck 2122 may include a dielectric plate, a lower electrode, an alternating current power source 2230, a first heater heating element 2240, a second heater heating element 2250, a first filter 2260, and a second filter 2270. The dielectric plate may constitute the body of the electrostatic chuck 2122. The dielectric plate may have a disk shape and may be made of a dielectric substance. The substrate W may be placed on the upper surface of the dielectric plate. The upper surface of the dielectric plate may have a diameter less than that of the substrate W. The edge region of the substrate W may be located outside the dielectric plate.

The alternating current power source 2230 may supply an alternating current signal to the first and second heater heating elements 2240 and 2250. The alternating current power source 2230 may supply the alternating current signal having a frequency in the range from 50 Hz to 60 Hz to cause the first and second heater heating elements 2240 and 2250 to generate heat.

The first and second heater heating elements 2240 and 2250 may each generate heat using the alternating current signal supplied from the alternating current power source 2230. A plurality of first and second heater heating elements 2240 and 2250 may be arranged over the whole area of the dielectric plate to heat the whole surface of the substrate W.

The first and second heater heating elements 2240 and 2250 may be coaxially arranged in the radius direction of the dielectric plate as shown in FIG. 12. Here, the heater arranged in a center region 2310 of the dielectric plate is defined as the first heater heating element 2240, and the heater arranged in an edge region 2320 is defined as the second heater heating element 2250.

The first filter 2260 may be interposed to connect the alternating current power source 2230 and the first heater heating element 2240. The first filter 2260 may pass the alternating current is signal flowing between the alternating current power source 2230 and the first heater heating element 2240 and filter out a noise signal flowing from the first heater heating element 2240 to the alternating current power source 2230.

The second filter 2270 may be interposed to connect the alternating current power source 2230 and the second heater heating element 2250. The second filter 2270 may pass the alternating current signal flowing between the alternating current power source 2230 and the second heater heating element 2250 and filter out a noise signal flowing from the second heater heating element 2250 to the alternating current power source 2230.

The heater heating elements 2240 and 2250 may be implemented using, for example, a printed circuit sintering process. That is, a pattern is printed using ink having particles in an emulsion state and heat is applied to the printed ink pattern to cause a plurality of particles contained in the ink to melt and thermally fuse together, so that the sintered heater heating elements 2240 and 2250 may be implemented on the dielectric plate. In order to minimize a temperature deviation of each of the heater heating elements 2240 and 2250, it is necessary to achieve a uniform amount of heat by adjusting, such as increasing or decreasing, the electrical resistance value of each of the heater heating elements 2240 and 2250.

Referring to FIGS. 12 and 7, a heating wire sintering resistance value may be measured according to locations 1 to 8 of the heater heating elements 2240 and 2250. Heating wire location numbers of FIG. 7 correspond to locations 1 to 8 shown in FIG. 12. If the measured heating wire sintering electrical resistance value is lower than a target resistance value, a trimming process may be performed on the corresponding heater heating element 2240 or 2250 to increase the electrical resistance value. The laser trimming process includes a process of removing a portion of the heater heating element 2240 or 2250 or changing physical properties of the heater heating element 2240 or 2250 by emitting laser light to the corresponding heater heating element 2240 or 2250. It is is confirmed that a resistance value of each of the heater heating elements 2240 and 2250 before applying the laser trimming process is at a level of approximately 250 to 260 whereas the resistance value of each of the heater heating elements 2240 and 2250 after applying the laser trimming process is increased to a level of 290.

However, when the heating wire sintering electrical resistance value is higher than a target resistance value, there is a problem in that the electrical resistance value cannot be lowered by performing a laser trimming process. In this case, the heater heating elements 2240 and 2250 have to be re-manufactured, which inevitably leads to a decrease in productivity.

According to an embodiment of the present disclosure, when the heating wire sintering electrical resistance value is higher than a target resistance value, a process of forming a resistance adjusting material layer on the heater heating elements 2240 and 2250 is introduced instead of the trimming process. The process of forming the resistance adjusting material layer may include, for example, a plating process, a deposition process, or a printing process. The plating process may include an electrolytic plating process. The resistance adjusting material layer may be a material layer made of the same material as the material constituting the heater heating elements 2240 and 2250 or a material layer including at least some elements of a compound constituting the heater heating elements 2240 and 2250.

According to an embodiment of the present disclosure, the resistance value of the heater heating element may be adjusted to a low level using the resistance adjusting material layer formed through electrolytic plating or may be adjusted to a high level using laser trimming. Accordingly, a resistance value adjustment time may be reduced by adjusting afterwards the heating wire sintering electrical resistance to approximate to the target resistance value, and a drawback of having to re-manufacturing the heater heating element in the case where the heating wire sintering electrical resistance value is higher than the target resistance value may be overcome.

Referring to FIGS. 12 and 8, the heating wire sintering resistance values according to locations 1 to 8 of the heater heating elements 2240 and 2250 may be in the range of 260 to 310. Assuming that a target resistance value is at a level of 290, regions corresponding to location 3 of the heater heating elements 2240 and 2250 have a heating wire sintering resistance value lower than the target resistance value and regions corresponding to location 6 of the heater heating elements 2240 and 2250 have a heating wire sintering resistance value higher than the target resistance value. In this case, the resistance values of the regions corresponding to location 3 of the heater heating elements 2240 and 2250 may be increased by selectively performing a laser trimming process and the resistance values of the regions corresponding to location 6 of the heater heating elements 2240 and 2250 may be decreased, so that a uniform resistance value over the entire heater heating elements 2240 and 2250 may be achieved. Meanwhile, the heater and a method of manufacturing the same according to an embodiment of the present disclosure described with reference to FIG. 9 or 10 may be applied to a substrate treatment apparatus for performing a dry etching process disclosed in FIG. 11.

So far, the heater, a method of manufacturing the same, and an apparatus for treating a substrate according to various embodiments of the present disclosure have been described. It is confirmed that the amount of heat generated can be made uniform not only through the configuration in which the region of the heater is divided in order to increase the temperature uniformity of the heater but also through the adjustment, such as increase or decrease, of a resistance value in order to minimize the temperature deviation in one heater region.

According to an embodiment of the present disclosure as described above, it is possible to implement a heater capable of attaining temperature uniformity, a method of manufacturing the heater, and an apparatus for treating a substrate. However, the scope of the present disclosure is not limited to the above-described effects.

While the present disclosure has been described with reference to an exemplary embodiment shown in the accompanying drawings, it is merely illustrative, and it will be understood by those of ordinary skill in the art that various changes and equivalent other embodiments may be made therefrom. Accordingly, the true scope of the present invention should be defined by the following claims.

A number of examples have been described above. Nevertheless, it will be understood that various modifications may be made. For example, suitable results may be achieved if the described techniques are performed in a different order and/or if components in a described system, architecture, device, or circuit are combined in a different manner and/or replaced or supplemented by other components or their equivalents. Accordingly, other implementations are within the scope of the following claims.

### REFERENCE NUMERALS

1: SUBSTRATE TREATMENT FACILITY
100: LOAD PORT
200: INDEX MODULE
300: FIRST BUFFER MODULE
400: COATING AND DEVELOPING MODULE
420, 470: BAKE UNIT
500: SECOND BUFFER MODULE
600: PRE/POST-EXPOSURE TREATMENT MODULE
620, 670: BAKE UNIT
700: INTERFACE MODULE
1400, 1420a, 1420b, 2124, 2240, 2250: HEATER HEATING ELEMENT

What is claimed is:

1. A method of manufacturing a heater, comprising:
performing a trimming process on at least a part of a heater heating element for heating a substrate; and
forming a resistance adjusting material layer on at least another part of the heater heating element.

2. The method of claim 1, wherein the forming of the resistance adjusting material layer comprises performing a plating process on at least another part of the heater heating element.

3. The method of claim 2, wherein the plating process comprises an electrolytic plating process.

4. The method of claim 1, wherein the forming of the resistance adjusting material layer comprises performing a deposition process on at least another part of the heater heating element.

5. The method of claim 1, wherein the forming of the resistance adjusting material layer comprises performing a printing process on at least another part of the heater heating element.

6. The method of claim 1, wherein the resistance adjusting material layer is made of the same material as a material constituting the heater heating element.

7. The method of claim 1, wherein the resistance adjusting material layer is a material layer comprising at least some elements of a compound constituting the heater heating element.

8. The method of claim 1, wherein, before performing the trimming process and forming the resistance adjusting material layer, an amount of heat generated by the heater heating element is measured and then performing the trimming process and forming the resistance adjusting material layer are performed on the basis of the measured amount of heat.

9. The method of claim 8, wherein the amount of heat generated in a first region that is at least a part of the heater heating element to which the laser trimming process is to be applied is relatively lower than the amount of heat generated in a second region that is at least another part of the heater heating element on which the resistance adjusting material layer is to be formed.

10. The method of claim 9, wherein the amount of heat generated in the first region that is is at least a part of the heater heating element is increased by performing the trimming process, and the amount of heat generated in the second region that is at least another part of the heater heating element is decreased by forming the resistance adjusting material layer.

11. The method of claim 8, wherein the amount of heat generated by the heater heating element is measured using a thermal imaging camera.

12. The method of claim 1, wherein, before performing the laser trimming process and forming the resistance adjusting material layer, an electrical resistance value of the heater heating element is performed, and then, performing the laser trimming process and forming the resistance adjusting material layer are performed on the basis of the electrical resistance value.

13. The method of claim 12, wherein an electrical resistance value of a first region that is at least a part of the heater heating element to which the trimming process is to be applied is relatively lower than an electrical resistance value of a second region that is at least another part of the heater heating element on which the resistance adjusting material layer is to be formed.

14. The method of claim 13, wherein the electrical resistance value of the first region that is at least a part of the heater heating element is increased by performing the laser trimming process, and the electrical resistance value of the second region that is at least another part of the heater heating element is decreased by forming the resistance adjusting material layer.

15. The method of claim 1, wherein the heater heating element before performing the is trimming process and forming the resistance adjusting material layer is implemented by a printed circuit sintering process.

16. A heater comprising a heater heating element configured to heat a substrate,
wherein at least a part of the heater heating element comprises a first region to which a trimming process is applied and at least another part of the heater heating element comprises a second region on which a resistance adjusting material layer is formed.

17. The heater of claim 16, wherein the resistance adjusting material layer is a plating layer implemented by a plating process on at least another part of the heater heating element.

18. The heater of claim 16, wherein the resistance adjusting material layer is a deposition layer implemented by a deposition process on at least another part of the heater heating element.

19. The heater of claim 16, wherein the resistance adjusting material layer is a material layer implemented by a printing process on at least another part of the heater heating element.

20. An apparatus for treating a substrate, comprising:
a process chamber capable of accommodating a substrate;
a support member provided in the process chamber and configured to support the substrate; and
a heater heating element provided in the support member and configured to heat the substrate,
wherein at least a part of the heater heating element comprises a first region to which a is laser trimming process is applied, at least another part of the heater heating element comprises a second region on which a resistance adjusting material layer is implemented by an electrolytic plating process, and
the amount of heat generated in the first region that is at least a part of the heater heating element is increased by performing the laser trimming process and the amount of heat generated in the second region that is at least another part of the heater heating element is decreased by forming the resistance adjusting material layer, so that a temperature distribution of the heater heating element is uniform.
